(19) United States
(12) Patent Application Publication
(10) Pub. No.: US 2009/0186214 A1
(43) Pub. Date: Jul. 23, 2009

(54) METHOD OF GROWING CARBON NANOMATERIALS ON VARIOUS SUBSTRATES

(75) Inventors: Khalid Lafdi, Fairborn, OH (US); Lingchuan Li, Dayton, OH (US)

Correspondence Address: DINSMORE & SHOHL LLP, ONE DAYTON CENTRE, ONE SOUTH MAIN STREET, SUITE 1300, DAYTON, OH, 45402-2023, US

(73) Assignee: UNIVERSITY OF DAYTON, Dayton, OH (US)

(21) Appl. No.: 12/301,096

(22) PCT Filed: May 15, 2007
(86) PCT No.: PCT/US07/11577

§ 371 Date: Dec. 17, 2008

Related U.S. Application Data
(60) Provisional application No. 60/800,944, filed on May 17, 2006.

(51) Int. Cl. B32B 33/00; C23C 16/44

(52) U.S. Cl. 428/336; 427/255.28; 428/688; 977/700; 977/891

(57) ABSTRACT

A method of growing carbon nanomaterials such as carbon πanotubes, carbon nanofibers, and carbon whiskers on a variety of substrates is provided which includes exposing at least a portion of the substrate surface to an oxidizing gas, followed by forming catalysts on the substrate surface, either by immersing the carbon substrate in a catalyst solution or by electrodeposition. The treated substrate is then subjected to chemical vapor deposition to facilitate the growth of carbon nanomaterials on the surface thereof. The carbon nanomaterials may be grown on a variety of substrates including carbon substrates, graphite, metal, metal alloys, intermetallic compounds, glass, fiberglass, and ceramic substrates.

This invention was made with government support under Contract No. FA8652-03-3-005 awarded by the Wright Brothers Institute, AFRL. The government has certain rights in the invention.

The present invention relates to a method of growing carbon nanomaterials such as carbon nanotubes, carbon nanofibers, and whiskers, and more particularly, to a method of growing carbon nanomaterials on a variety of substrates which provides controlled growth and density of the carbon nanomaterials.

Carbon nanotubes and other carbon nanomaterials have been widely studied due to their unusual properties including high thermal conductivity. Many techniques are known for growing carbon nanotubes on substrates including arc discharge, enhanced plasma vapor deposition (PVD), and chemical vapor deposition (CVD). However, many of the techniques currently in use have a number of limitations. For example, it is difficult to control the uniformity and thermal conductivity of the carbon nanotubes for certain applications, and it is difficult to increase the density of a carbon nanotube skeleton during growth.

In addition, because carbon nanotube growth is a substrate-related process, the use of metal catalysts such as Ni, Fe and Co have the potential to diffuse too fast onto the substrate and coalesce into larger particles, leading to the formation of large metal particles, thus reducing catalyst particle density and potential for carbon nanotube growth.

It would be desirable to be able to grow carbon nanomaterials such as nanotubes, nanofibers, and whiskers on substrates while controlling the density, alignment, and conductivity of such materials so that they may be used as high thermal conductive adhesives or conductive interface materials for providing tailored electrical conductivity. It would also be desirable to grow carbon nanomaterials on a variety of substrates including carbon-based substrates, glass-based substrates, metals, intermetallic compounds, and ceramics.

Accordingly, there is still a need in the art for a method of growing carbon nanomaterials on a variety of substrates which allows the density and growth of the materials to be controlled.

The present invention meets that need by providing a method of growing carbon nanomaterials such as nanotubes, nanofibers, and whiskers on the surface of various substrates in which the substrate surfaces are functionalized prior to growth of the carbon nanomaterials to provide controlled growth and density of the carbon nanomaterials grown thereon. The method controls the rate of diffusion of catalytic metals on the substrates and may include the use of nickel, molybdenum, iron and cobalt catalysts.

According to one aspect of the present invention, a method of growing carbon nanomaterials on a substrate is provided which comprises providing a substrate having a surface; exposing at least a portion of the surface of the substrate to an oxidizing gas; forming catalysts on the surface of the substrate by immersing the substrate in a catalyst solution or subjecting the substrate to electrodeposition; and subjecting the surface of the substrate to chemical vapor deposition to facilitate the growth of carbon nanomaterials. By “carbon nanomaterials,” it is meant carbon nanotubes, carbon nanofibers and carbon whiskers. The type of carbon nanomaterial grown is determined by the method parameters, i.e., temperature, gas used in chemical vapor deposition, type of substrate, etc.

The substrate is preferably selected from carbon, graphite, metal, metal alloys, glass, fiberglass, ceramic, and intermetallic compounds.

Where the substrate is selected from metal, metal alloys, graphite, and intermetallic compounds, the catalyst may be formed on the substrate by electrodeposition. The electrodeposition may include the presence of a reductant. The reductant may comprise sodium hypophosphite.

In embodiments where the substrate comprises carbon, the carbon substrate may be selected from carbon fibers, carbon nanofibers, carbon films, carbon foam, carbon fabric, and carbon fiber bundles. In this embodiment, the catalysts may be formed on the substrate by immersing the substrate in the catalyst solution.

The oxidizing gas is selected from ozone, carbon dioxide, and mixtures thereof. The substrate may be exposed to the oxidizing gas at a temperature of between about 100° C. and 900° C. Where the oxidizing gas comprises ozone, the substrate is exposed at a temperature of between about 100° C. and about 200° C., and where the oxidizing gas comprises carbon dioxide, the substrate is exposed at a temperature of between about 400° C. and about 900° C.

The catalyst solution comprises a water or alcohol solution and soluble salts. The soluble salts in the solution are selected from iron, molybdenum, nickel, cobalt, and combinations thereof. The method may include drying the substrate after immersing the substrate in the solution.

The chemical vapor deposition takes place at a temperature between about 600° C. and about 900° C., and utilizes hydrocarbon gases selected from acetylene, ethylene, methane, and combinations thereof.

In one embodiment of the present invention, the method provides a substrate including carbon nanotubes on the surface thereof, where the carbon nanotubes have a thickness of from about 100 nm to about 30 μm.

The method of the present invention overcomes previous problems of nanomaterial dispersion and diffusion during composite processing. By growing carbon nanomaterials on a treated substrate, problems which have previously occurred relating to nanocomposite infiltration during composite fabrication are eliminated. In addition, the carbon nanomaterials increase the interlaminar sheer and thermal resistivity of composites formed from the carbon nanomaterials. Because of the electrical and thermal conductivity and the chemical stability of carbon, carbon nanomaterials formed by the method of the present invention may be used in EMI shielding applications, contact thermal resistance applications, and in ultracapacitors. The carbon nanomaterials are also useful in biomedical applications, such as to promote bone and skin healing. For example, carbon nanomaterials may be grown on a metal prosthetic device to increase the body's compatibility to the carbon surface of the device.

Accordingly, it is a feature of the invention to a provide a method of growing carbon nanomaterials on a variety of substrates which provides controlled growth and density of the resulting materials. Other features and advantages will be apparent from the following description, the accompanying drawings, and the appended claims.

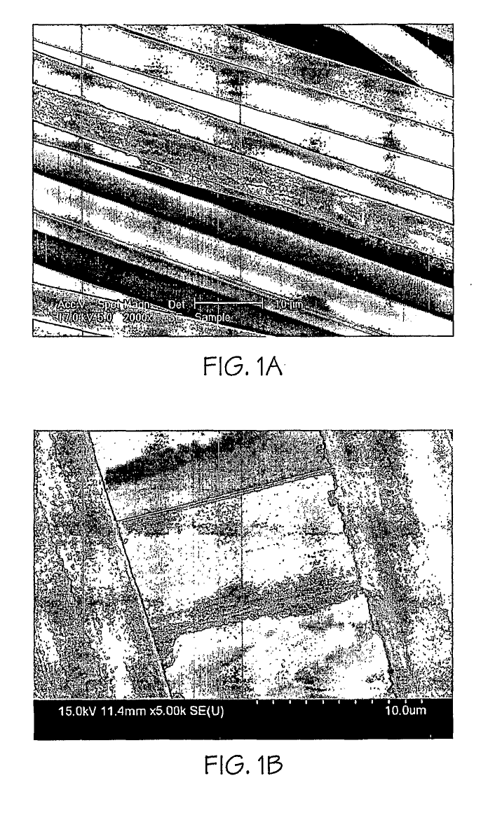

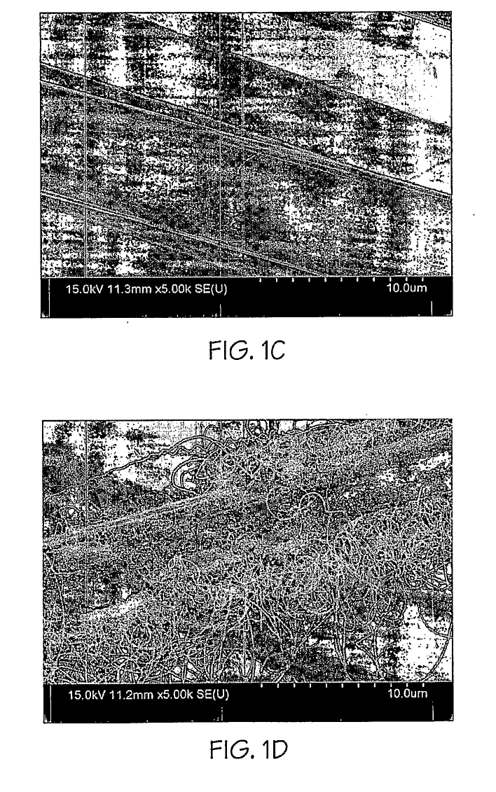

FIG. 1(a-d) illustrates the growth of carbon nanotubes on a carbon fiber substrate without the surface treatment of the method of the present invention; and

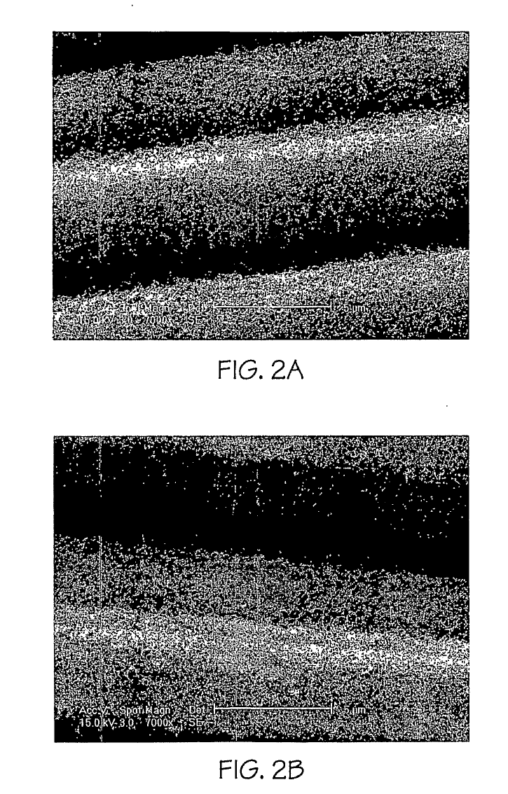

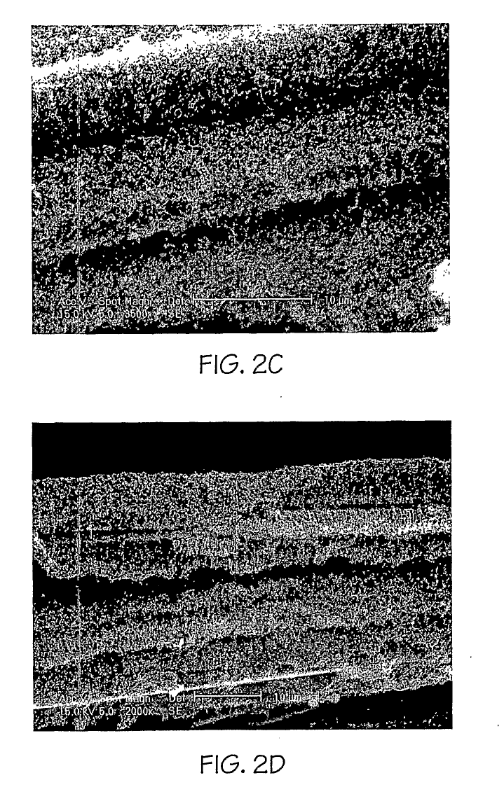

FIG. 2(a-d) illustrates the growth of carbon nanotubes on carbon fiber substrates which have been surface treated in accordance with the method of the present invention.

The method of the present invention provides several advantages over prior methods of growing carbon nanomaterials in that the functionalization of the substrate surface by gas oxidation allows a strong bond to be created between the substrate and the nanomaterials grown thereon. The functionalization also allows the growth and density of the carbon nanomaterials to be controlled.

The carbon nanomaterials grown in the method of the present invention include carbon nanotubes, carbon nanofibers, and whiskers. The nanotubes formed are typically multi-walled nanotubes, but with the use of certain substrates such as carbon nanofibers and quartz, a combination of multi-walled and single-walled carbon nanotubes may be formed. The type of carbon nanomaterial grown is generally determined by the method parameters, i.e., type of catalyst metal, temperature, gas used in chemical vapor deposition, type of substrate, etc. For example, the use of carbon substrate, a nickel catalyst in the catalyst solution and performing chemical vapor deposition at about 600° C. under atmospheric pressure using acetylene as the carbon source results in the formation of carbon nanofibers. Where a carbon or other substrate and iron and iron-molybdenum bi-metal catalysts are used, and the chemical vapor deposition is conducted at about 780° C. using ethylene as the carbon source, multi-walled carbon nanotubes are formed. Carbon whiskers may be formed when using a carbon or other type of substrate with an iron catalyst in the solution and conducting chemical vapor deposition between about 1000 and 1100° C. using methane as the carbon source.

Suitable substrates for use in the present invention include, but are not limited to, carbon, graphite, metal, metal alloys, ceramic, glass, fiberglass, and intermetallic compounds. Examples of carbon substrates include carbon fibers (including PAN and mesophase-based carbon fibers), carbon nanofibers, films, foam, fabric, and fiber bundles. Examples of graphite substrates include graphite fibers, foils, plates and rods. Examples of metal substrates include aluminum, chromium, nickel, copper, titanium, and the like. Suitable alloy substrates include stainless steel, aluminum alloys, and titanium alloys. Suitable intermetallic compounds for use as substrates include TiAl, FeAl, Fe₃Al, NiAl, Ni₃Al, and the like.

Where fiberglass materials are used as substrates, it should be appreciate that in addition to conventional fiberglass, glass fiber materials may be used which have catalysts already incorporated on their surface (commercially available from Dow Corning).

In the method of the present invention, the surface of the substrate on which the carbon nanomaterials are grown is functionalized by introducing an oxidizing gas into a chamber or container containing the substrate at a temperature of between about 100 to 200° C., and preferably, about 150° C., and a pressure of about 1 atm for between about 5 and 30 minutes. The oxidizing gas may comprises ozone or carbon dioxide, which increases the surface wettability and surface energy of the substrate.

After the substrate surface is functionalized, the substrate is either immersed in a catalyst solution, or subjected to electrodeposition to facilitate the formation of catalysts on the substrate surface, rendering it suitable for growing carbon nanomaterials. The method used depends on the type of substrate. Generally, a solution-based catalyst should be used when the substrate to be functionalized is not electrically conductive. In instances where the substrate is electrically conductive, i.e., where graphite, metal, metal alloys, and intermetallic substrates are used, an electrodeposition method is used for applying the catalysts.

It should be appreciated that for some forms of carbon such as carbon fibers, fabrics, and bundles, either the solution-based catalyst method or electrodeposition method may be used, but solution-based catalysts are preferred. When using carbon nanofibers provided in powder form, the solution-based catalyst method should be used.

In the solution-based catalyst method, the substrate is immersed in a catalyst solution comprised of water or alcohol and soluble salts of nickel, molybdenum, iron or cobalt (or combinations thereof) for about 1 second up to 10 minutes, and more preferably, from about 10 seconds to 5 minutes. The substrate may then be air dried at room temperature or dried by heating. As the substrate dries, catalysts form and spread to the surface of the substrate, rendering it suitable for growing carbon nanomaterials.

The electrodeposition method includes subjecting the surface of the substrate to electrodeposition in the presence or absence of a reductant such as sodium hypophosphite, and may be performed in an electroless deposition bath. The use of the reductant facilitates the uniform formation of catalytically active nanoparticles on the substrate surface and helps to preserve and stabilize the formed nanoparticles that are typically unstable when in contact with the acidic electrodeposition solution and water. In the electrodeposition method, a current or potential is applied to the substrate in the bath for a time sufficient to form nuclei on the substrate, and the substrate is held in the solution for a few minutes before removing it. A second application of current or potential may then be applied with the substrate placed in the bath. This process is similar to conventional pulse electrodeposition, but is performed in the presence of reductants.

Where the substrate is aluminum, the electrodeposition may utilize 110V, 60 HZ alternate power. The voltage may be obtained from a transformer which lowers the original 110 V voltage. The electrodeposition has been found to provide formation of about 10 nm amorphous aluminum oxide on the surface of substrates such as aluminum or aluminum alloys. Thus, the growth of carbon nanotubes or carbon nanofibers on such substrates results in an excellent electrical connection with the substrates.

After the formation of catalysts on the substrate surface, the substrate is subjected to chemical vapor deposition at a temperature ranging from between about 600° C. and 900° C, and a pressure of 1 atm. The chemical vapor deposition may include the use of various gas phase carbon sources including hydrocarbon gases such as acetylene, ethylene and methane to facilitate the growth of carbon nanomaterials. The growth is controlled by monitoring the reaction time for a time ranging from about 3 to 15 minutes.

The growth of carbon nanotubes may be tailored such that the resulting carbon nanotubes have a thickness of between about 100 nm to 30 μm and a conductivity of between about 6 and 10 W/m.K.

In order that the invention may be more readily understood, reference is made to the following examples which are intended to illustrate the invention, but not limit the scope thereof.

### EXAMPLE 1

Carbon nanotubes were grown on carbon fiber substrates in accordance with the method of the present invention including the gas oxidizing substrate surface treatment at a temperature of about 150 ° C. for about 5 minutes. The carbon fiber substrates were then immersed in a water/alcohol solution containing iron and molybdenum salts.

Carbon nanotubes were then grown on the treated substrates under the following conditions: (gas type: acetylene and ethylene; gas flow: 150 ml/min., temperature: 600° C.; growth time: 10 minutes). Another set of carbon nanotubes were grown on carbon fiber substrates using the same growth conditions described above, but without the surface treatment. The results are shown in FIGS. 1 and 2. As shown in FIG. 1, carbon nanotubes were essentially unable to grow on the surface of carbon substrates which were not modified by the gas oxidation treatment of the present invention.

In contrast, as shown in FIG. 2, more carbon nanotubes grew uniformly on the carbon fiber substrates which were surface treated by gas oxidation. As shown, thick and aligned carbon nanotube structures were observed on the carbon fiber substrates. The results of X-ray photoelectron spectroscopy (XPS) analysis showed a substantial increase in surface concentration of oxygen and change of surface energy after the surface treatment.

### EXAMPLE 2

Co and Ni catalysts were applied to copper and titanium substrates by electrodeposition in electroless deposition baths containing a NaH₂PO₂.H₂O reductant. A potential was applied to the substrate to initiate formation of catalyst nanoparticles. The formation of the nanoparticles spread uniformly across the substrates.

The substrates were then subjected to chemical vapor deposition at a temperature of about 600° C. using a gas flow containing 5 ml/l acetylene for about 50 to 10 minutes. This facilitated the growth of carbon nanofibers on the substrates.

Having described the invention in detail and by reference to preferred embodiments thereof, it will be apparent that modifications and variations are possible without departing from the scope of the invention.

1. A method of growing carbon nanomaterials on a substrate comprising:
providing a substrate having a surface;
exposing at least a portion of said surface of said substrate to an oxidizing gas;
forming catalysts on the surface of said substrate by immersing said substrate in a catalyst solution or subjecting said substrate to electrodeposition; and
subjecting said surface of said substrate to chemical vapor deposition to facilitate growth of carbon nanomaterials.

2. The method of claim 1 wherein said substrate is selected from carbon, graphite, metal, metal alloys, ceramic, glass, fiberglass, ceramic, and intermetallic compounds.

3. The method of claim 1 wherein said substrate comprises metal, metal alloys, intermetallic compounds, or graphite, and wherein said catalysts are formed on said substrate by electrodeposition.

4. The method of claim 3 wherein said substrate is subjected to electrodeposition in the presence of a reductant.

5. The method of claim 4 wherein said reductant comprises sodium hypophosphite.

6. The method of claim 1 wherein said substrate comprises a carbon substrate selected from carbon fibers, carbon nanofibers, carbon films, carbon foam, carbon fabric, and carbon fiber bundles.

7. The method of claim 6 wherein catalyst are formed on said carbon substrate by immersing said substrate in said catalyst solution.

8. The method of claim 1 including drying said substrate after immersing said substrate in said catalyst solution.

9. The method of claim 1 wherein said oxidizing gas is selected from ozone, carbon dioxide, and mixtures thereof.

10. The method of claim 1 wherein said substrate is exposed to said oxidizing gas at a temperature of between about 100° C. and 900° C.

11. The method of claim 1 wherein said oxidizing gas comprises ozone and said substrate is exposed to said gas at a temperature of between about 100° C. and 200° C.

12. The method of claim 1 wherein said oxidizing gas comprises carbon dioxide and said substrate is exposed to said gas at a temperature of between about 400° C. and 900° C.,

13. The method of claim 1 wherein said chemical vapor deposition takes place at a temperature between about 600° C. to 900° C.

14. The method of claim 1 wherein said chemical vapor deposition utilizes hydrocarbon gases selected from acetylene, ethylene, methane, and combinations thereof.

15. The method of claim 1 wherein said catalyst solution comprises water or alcohol and soluble salts.

16. The method of claim 1 wherein said soluble salts are selected from iron, molybdenum, nickel, cobalt, and combinations thereof.

17. A substrate including carbon nanomaterials on the surface thereof formed by the method of claim 1.

18. The substrate of claim 17 wherein said carbon nanomaterials have a thickness of from about 100 nm to about 30 μm.
